(19) United States
(12) Patent Application Publication
(10) Pub. No.: US 2023/0021169 A1
(43) Pub. Date: Jan. 19, 2023

(54) SEMICONDUCTOR DEVICE WITH DEEP TRENCH AND MANUFACTURING PROCESS THEREOF

(71) Applicant: Analog Power Conversion LLC, Bend, OR (US)

(72) Inventors: Dumitru Gheorge SDRULLA, Bend, OR (US); Amaury GENDRON-HANSEN, Bend, OR (US)

(21) Appl. No.: 17/374,734

(22) Filed: Jul. 13, 2021

(51) Int. Cl. H01L 29/40; H01L 29/66; H01L 29/78

(52) U.S. Cl. CPC H01L 29/407; H01L 29/66734; H01L 29/7813

(57) ABSTRACT

A semiconductor device is formed having a deep trench, a conductive material disposed in the deep trench, and a dielectric disposed within the deep trench and separating the conductive material from surfaces of the deep trench. The conductive material may be carbon, and may be formed by pyrolysis of an organic material such as a photoresist. The deep trench and the conductive material may be parts of a high-voltage termination of an active device of the semiconductor device. The conductive material may be floating or may be connected to an electrode of the active device.

### BACKGROUND

Semiconductor devices may be fabricated with deep trenches. As used herein, a deep trench is a trench whose bottom is deeper than a metallurgical junction of an implant in the semiconductor, and that may penetrate through most of or an entirety of a layer of the semiconductor device that active devices are fabricated in, such as an epitaxial layer. In devices having the epitaxial layer formed on a substrate, the deep trench may partly penetrate the substrate as well. These trenches may be filled with a dielectric, such as an oxide, or (in low voltage applications) with undoped polysilicon.

One use for deep trenches is in edge termination of the active area of a semiconductor device. These edge terminations may operate to spread the electrostatic potential at the edges of the device, thereby increasing a breakdown voltage of the device. Accordingly, these edge terminations may also be referred to as high-voltage terminations.

A high-voltage termination may include a field plate formed in a metal layer, coupled to an electrode of the semiconductor device, and extending over a portion of a deep trench. To provide a high breakdown voltage (for example, higher than 1200 V) the trench must not only be deep but also must be relatively wide. Typically, a wide trench has a width that is at least half the depth of the trench.

Reliably filling a wide deep trench with a material both capable of supporting such high breakdown voltage and compatible with later processing steps of the semiconductor may be difficult, especially in semiconductor technologies that require high temperatures in processing steps that follow the formation and filling of the wide deep tranches.

### SUMMARY OF THE INVENTION

Embodiments relate to semiconductor devices and manufacturing processes thereof, and in particular to semiconductor devices including deep trenches and processes for filling such deep trenches.

In embodiments, a semiconductor device comprises a deep trench, a conductive material disposed in the deep trench, and a dielectric disposed within the deep trench and separating the conductive material from surfaces of the deep trench.

In an embodiment, the conductive material is carbon.

In an embodiment, the carbon is formed by pyrolysis of an organic material such as a photoresist.

In an embodiment, the deep trench and the conductive material operate as part of a high-voltage termination of an active device of the semiconductor device.

In embodiments, a method of manufacturing a semiconductor device comprises forming a trench in the semiconductor device, depositing an organic compound within the trench; and converting the organic compound to a carbon fill by converting the organic compound to carbon using pyrolysis.

In an embodiment, the organic compound is thinned before it is converted to carbon.

In an embodiment, the trench includes a layer of dielectric disposed over surfaces of the trench. The layer of dielectric may be formed before the organic compound is deposited.

In an embodiment, a dielectric layer may be formed over the carbon fill.

In an embodiment, the organic compound is a photoresist.

### BRIEF DESCRIPTION OF THE DRAWINGS

FIG. 1 illustrates a semiconductor device according to an embodiment.

FIG. 2 illustrates a semiconductor device according to another embodiment.

FIG. 3A illustrates a semiconductor device according to another embodiment.

FIG. 3B illustrates a semiconductor device according to another embodiment.

FIGS. 4A through 4H illustrate steps in a semiconductor device manufacturing process according to an embodiment.

FIGS. 5A and 5B illustrate additional steps performed after the steps shown in FIGS. 4A through 4H in a semiconductor device manufacturing process according to an embodiment.

FIGS. 6A and 6B illustrate additional steps performed after the steps shown in FIGS. 5A and 5B in a semiconductor device manufacturing process according to an embodiment.

FIG. 7 illustrates an additional step performed after the steps shown in FIGS. 5A and 5B in a semiconductor device manufacturing process according to another embodiment.

FIGS. 8A through 8C illustrate additional steps performed after the steps shown in FIGS. 4A through 4H in a semiconductor device manufacturing process according to an embodiment.

FIG. 9 illustrates an additional step performed after the steps shown in FIGS. 8A through 8C in a semiconductor device manufacturing process according to another embodiment.

FIG. 10 illustrates an additional step performed after the steps shown in FIGS. 8A through 8C in a semiconductor device manufacturing process according to another embodiment.

FIG. 11 illustrates a cross-section of a semiconductor device according to an embodiment.

FIG. 12 illustrates a cross-section of a semiconductor device according to another embodiment.

FIG. 13 illustrates a cross-section of a semiconductor device according to another embodiment.

FIG. 14 is a graph of breakdown voltage for devices according to embodiments.

FIG. 15 is a graph of junction capacitance for devices according to embodiments.

### DETAILED DESCRIPTION

Embodiments of the present application relate to the filling of trenches in semiconductor devices, such as deep trenches used to provide high-voltage terminations. In embodiments, a trench in a semiconductor device is filled with an organic material, such as a photoresist, and then the organic material is converted to carbon by pyrolysis.

A detailed description of embodiments is provided below along with accompanying figures. The scope of this disclosure is limited only by the claims and encompasses numerous alternatives, modifications, and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

Power semiconductor devices require a dedicated high-voltage termination to avoid early breakdown at an active area periphery. However, structures used for high-voltage termination come with a significant parasitic capacitance which negatively affects the high-frequency switching performance and, depending on the design and material used, have hysteresis properties, unsuitable for high-frequency operations. To mitigate this issue, deep trench terminations were developed, but at the expense of a higher process complexity to fill the trench.

Super-junction technologies commonly rely on deep trenches etch and semiconductor epitaxial growth fill. The focus of these technologies is to optimize the trade-off between a low on-state resistance and a high blocking voltage, In particular, super-junction devices can break the conventional silicon limit for power semiconductor devices. However, this concept is not suitable for high-voltage terminations and super-junction devices need specific high-voltage termination designs.

Narrow trenches filled with polysilicon are widely used in low-voltage silicon technologies. But this technique is not a viable option to fill the wide trenches required for high-voltage technologies.

Filling wide deep trenches with oxides can be problematic because voids and crevasses may form in the oxide as it is deposited. This makes the characteristics of the deposited oxide somewhat unpredictable and makes the oxide difficult to planarize.

Filling deep trenches with other dielectrics, such as polyimide or benzocyclobutene (BCB), may be impractical because these materials may be unstable at temperatures used in later steps of the manufacturing process: polyimides are unstable above 500° C., and BCB above 350° C., while some steps in the fabrication of high band-gap semiconductors such as silicon carbide (SiC) require temperatures of 700 to 1200° C., or higher.

Polysilicon can be used to fill trenches but is not usable for high-voltage terminations with high breakdown voltages. Trenches for high-voltage SiC technology must be wide to provide an adequate blocking voltage, and a thick polysilicon deposition would be required to fill them. Thick polysilicon films are not practical, in particular due to wear-out of the equipment (tube) in which the deposition of the polysilicon is performed. As a result, typical polysilicon thicknesses are less than 0.6 which is insufficient to fill a wide trench. Furthermore, the high dielectric constant of polysilicon makes it difficult to design polysilicon-filled trenches with a high blocking voltage.

Embodiments include high-voltage terminations for a semiconductor device, the high-voltage termination comprising a deep trench filled with an interfacial dielectric layer and a conductive material to provide a high blocking voltage with a low parasitic capacitance. In embodiments, the conductive material is carbon, and the carbon is formed in the trench by depositing a layer of organic material such as a photoresist and converting the organic material to carbon by pyrolysis.

In an embodiment, the surfaces of the trench are passivated, a thin interfacial dielectric layer (silicon dioxide (SiO₂)) is formed on the surfaces of a trench, and then a thick interfacial dielectric layer and a conductive material are deposited to fill the remainder of the trench. The thin interfacial dielectric layer can be either kept (liner oxide) or removed (sacrificial oxide) before the next process step. When used as a high-voltage termination, this structure provides a very efficient field plate effect when the conductive material is electrically grounded (including to a virtual ground), and a blocking voltage above 95% of the epitaxy capability can be achieved. If the conductive layer is electrically floating, the parasitic capacitance of the high-voltage termination is reduced, at the expense of a lower blocking voltage.

Best results are achieved with deep trenches; ideally through the whole epitaxy layer, but at least deeper than a metallurgical junction of a doped structure (such as a p-well) of the device. A large trench width is also beneficial for the blocking voltage and well-suited to the manufacturing process of the embodiments.

To overcome the difficulties with filling a deep trench, manufacturing processes according to embodiments are based on the deposition of a photoresist and subsequent conversion of the photoresist to carbon by pyrolysis (heat). A photoresist deposition provides an excellent filling (no holes or cracks) and is easily planarized by spinning. The etch of the photoresist is also a standard process with excellent uniformity

Embodiments are particularly well-suited for SiC technologies (which may have a thin epitaxy layer and high-voltage rating) but is also applicable to a wide range of other semiconductor materials, including but not limited to silicon and gallium nitride (GaN). The pyrolysis-formed carbon provides a conductive element that fills the entire trench and conforms well to the imperfections of the thick interfacial dielectric layer of the trench, preventing the formation of mounds, bumps, and valleys. Furthermore, during the pyrolysis process, the photoresist will induce less stress than trench-filling technologies of the related art.

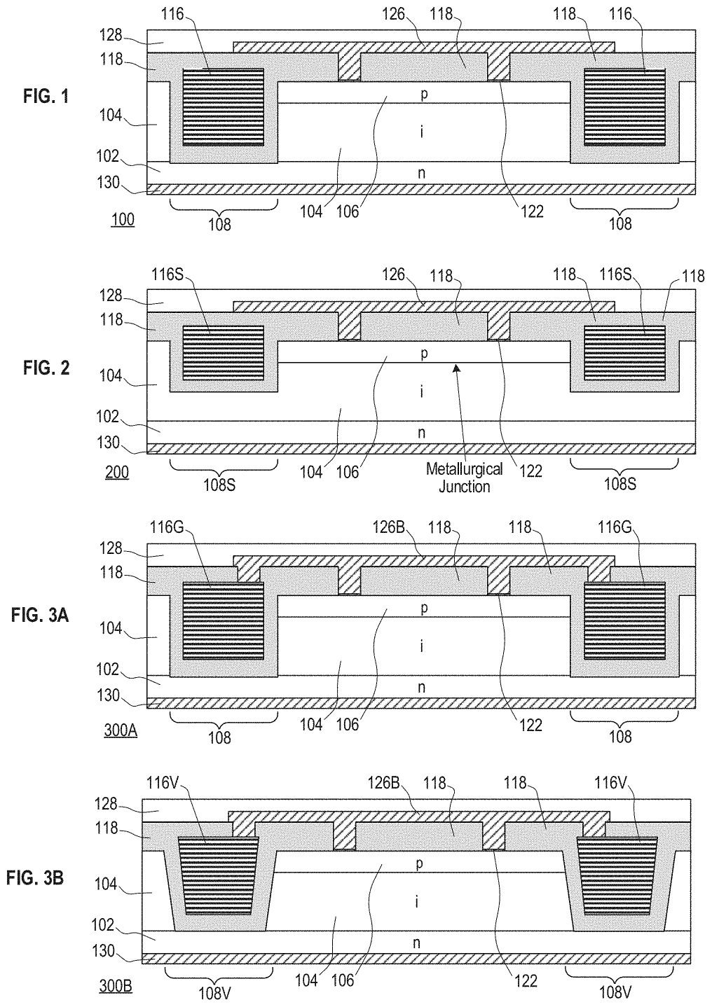

FIG. 1 illustrates a semiconductor device 100 according to an embodiment. The device 100 is a vertical PIN diode, but embodiments are not limited thereto.

The device 100 comprises a substrate 102 on which an epitaxial layer (hereinafter, the epitaxy 104) has been formed. In embodiments, the substrate 102 and epitaxy may be a wide bandgap semiconductor such as SiC, and may be n-type material, but embodiments are not limited thereto.

A doped region 106 is formed in the epitaxy 104 between two deep trenches 108. In the illustrated PIN diode, the doped region 106 is a p-type region, but embodiments are not limited thereto.

Each of the trenches 108 is lined with an dielectric 118 that is also formed over the top of the epitaxy 104 and the doped region 106. In embodiments, the dielectric 118 includes silicon dioxide.

A carbon fill 116 is formed inside the dielectric 118 lining each trench 108. In embodiments, the carbon fill 116 is formed by pyrolysis of an organic material, such as a photoresist. The carbon fill 116 in the embodiment of FIG. 1 is “floating,” in that it is not electrically connected to any of the active portions of the device 100. As shall be explained below, compared to an alternative, this produces a lower junction capacitance at the expense of a lower breakdown voltage.

A first electrode 126 is formed over and in electrical contact with the doped region 106 and extends over at least part of carbon fill 116 in the trenches 108. The first electrode 126 provides an electrical connection to an anode of the vertical PIN diode comprised of the doped region 106, the portion of the epitaxy 104 below the doped region 106, and the substrate 102.

The first electrode 126 may comprise aluminum, among other conductors, and may be electrically connected to the doped region 106 through a thin metal layer 122, which in an embodiment may comprise nickel silicide.

The portion of the first electrode 126 extending over the carbon fill 116 in the trenches 108 may operate as a field plate to increase the breakdown voltage of the PIN diode of device 100.

A second electrode 130 comprising a conductor, such as silver, is formed over a bottom surface of the substrate 102 and provides an electrical connection to a cathode of the PIN diode.

A passivation layer 128 is formed over the electrode 126 and the dielectric 108. In embodiments, the passivation layer comprises silicon oxynitride (SiON).

FIG. 2 illustrates a cross-section of a semiconductor device 200 according to another embodiment. The device 200 differs from the device 100 of FIG. 1 in that:

the trenches 108S of FIG. 2 are not as deep as the trenches 108 of FIG. 1, and accordingly,

the carbon fill 116S of FIG. 2 is not as deep as the carbon fill 116 of FIG. 1.

The trenches 108S are still deep trenches because they are still deeper than the metallurgical junction between the bottom of the doped region 106 and the epitaxy 104.

FIG. 3A illustrates a semiconductor device 300A according to another embodiment. The device 300A differs from the device 100 of FIG. 1 in that the carbon fill 116G in the trenches 108 is considered “grounded,” because it is electrically connected to the anode of the PIN diode of the device 300A by the first electrode 126B.

Compared to the floating carbon fill 116 of FIG. 1, the grounded carbon fill 116G provides a higher breakdown voltage at the expense of a higher junction capacitance.

FIG. 3B illustrates a semiconductor device 300B according to another embodiment. The device 300B differs from the device 300A of FIG. 3A in that the trenches 108V have sloped (instead of vertical) side walls, and accordingly the grounded carbon fill 116V in the trenches 108V has sloped sidewalls as well.

Although FIG. 3B illustrates a semiconductor device 300B with the grounded carbon fill 116V and the trenches 108V extending through the entire depth of the epitaxy 104, embodiments are not limited thereto, and embodiments with floating carbon fills, trenches that do not extend the full depth of the epitaxy, or both may have trenches with sloped side walls as well. Embodiments with sloped trench side walls may be easier to manufacture than embodiments with vertical trench side walls, while still providing excellent electrical performance.

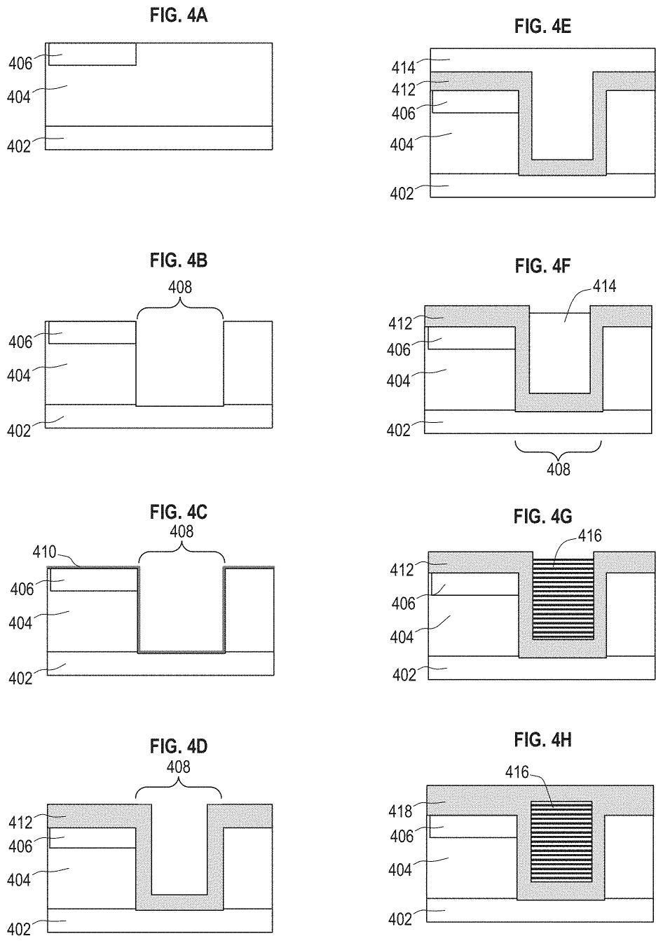

FIGS. 4A through 10 illustrate processes of forming a semiconductor device according to several embodiments. Where techniques for creating a structure shown in FIGS. 4A through 10 are well-known in the related arts (for example, the forming of layers by deposition followed by photolithography), descriptions of the techniques are omitted in the interest of brevity.

FIGS. 4A through 4H illustrate steps in a semiconductor device manufacturing process according to an embodiment. Numbers of the form 1xx appearing FIG. 1 correspond to numbers in the form 4xx in FIGS. 4A-4H, and respectively correspond to the substantially identical structures.

FIG. 4A shows a substrate 402, an epitaxy 404, and a doped region 406.

At FIG. 4B, a trench 408 has been formed through the full depth of the epitaxy 404, and a small amount into the substrate 404. However, embodiments are not limited to full-depth trenches, and in embodiments, the trench 408 stops part way into the epitaxy 406, like the trench 108S of FIG. 2. A portion of the doped region 406 was removed during the trench formation so that the metallurgical junction between the doped region 406 and the epitaxy 406 ends in contact with the side-wall of the trench.

At FIG. 4C, a thin oxide layer 410 has been formed over the surface of the trench 408 and over the top surface of the doped region 406 and epitaxy 404. The thin oxide layer 410 may comprise silicon dioxide grown by thermal oxidation.

Forming a thin oxide layer 410 passivates the surface of the trench 408, which can improve, among other characteristics, the leakage current and the breakdown voltage of the device. However, forming the thin oxide layer 410 is optional.

At FIG. 4D, a thicker dielectric layer 412 has been formed in the trench 408 and over the top of the epitaxy 404 and doped region 406. In embodiments where the thin oxide layer 410 is formed, the dielectric layer 412 may incorporate the thin oxide layer 410. In embodiments, the dielectric layer 412 may comprise silicon dioxide.

At FIG. 4E, an organic material 414, such as a photoresist, has been formed over the dielectric layer 412. The organic material 414 may be formed over the device by, for example, spin coating.

At FIG. 4F, the portions of the organic material 414 not in the trench 408 are removed.

At FIG. 4G, the organic material 414 remaining in the trench has been converted into carbon fill 416 by pyrolysis. For example, the organic material 414 may have been a positive photoresist such as AZ4330 from Hoechst Celanese, Somerville, N.J., or a negative photoresist such as AZ nLOF 2070 from MicroChemicals GmbH, Ulm, Germany, and may have been pyrolyzed at 700° C. or more to produce the carbon fill 416.

At FIG. 4H, additional dielectric is formed over the carbon fill 416 and the dielectric layer 412 to form the dielectric layer 418. The dielectric layer 418 may incorporate the dielectric layer 412 of FIG. 4G. In embodiments, the dielectric layer 418 may comprise silicon dioxide.

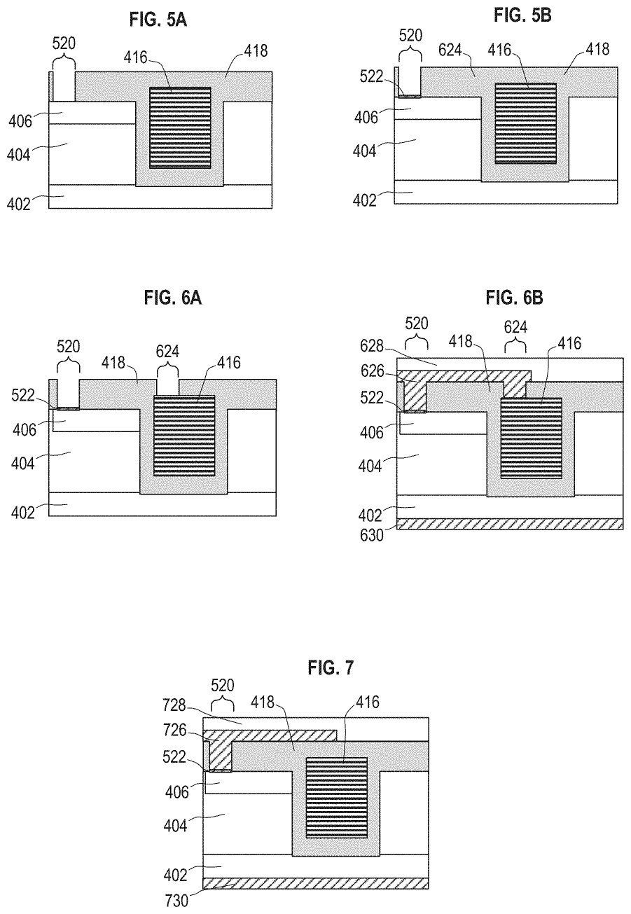

FIGS. 5A and 5B illustrate additional steps performed after the steps shown in FIGS. 4A through 4H in a semiconductor device manufacturing process according to an embodiment.

At FIG. 5A, a first contact opening 520 has been formed through the dielectric layer 418 to expose a portion of the doped region 406.

At FIG. 5B, a thin conductive layer 522, which may comprise nickel silicide, has been formed at the bottom of the first contact opening 520 on the doped region 406.

FIGS. 6A and 6B illustrate additional steps performed after the steps shown in FIGS. 5A and 5B in a semiconductor device manufacturing process according to an embodiment.

At FIG. 6A, a second contact opening 624 has been formed through the dielectric layer 418 to expose a portion of the carbon fill 416.

At FIG. 6B, a first electrode 626 has been formed to provide an electrical connection to the doped region 406 and the carbon fill 416. In this embodiment, the carbon fill 416 is electrically grounded and corresponds to the carbon fill 116G of FIG. 3A or the carbon fill 116V of FIG. 3B. Then a passivation layer 628 has been formed over the device.

FIG. 7 illustrate an additional step performed after the steps shown in FIGS. 5A and 5B in a semiconductor device manufacturing process according to another embodiment.

At FIG. 7, a first electrode 726 is formed to provide an electrical connection to the doped region 406. In this embodiment, the carbon fill 416 is electrically floating and corresponds to the carbon fill 116 of FIG. 1. Then a passivation layer 728 has been formed over the device.

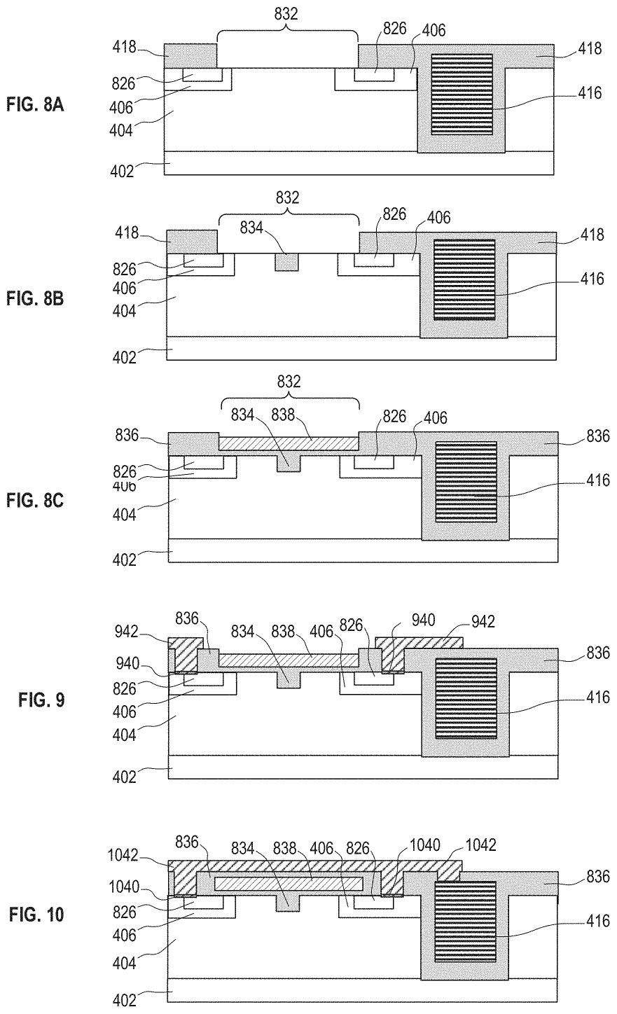

FIGS. 8A, 8B, and 8C illustrate additional steps performed after the steps shown in FIGS. 4A through 4H in a semiconductor device manufacturing process according to an embodiment. FIGS. 8A, 8B, 8C, 9 and 10 that follow show steps in the fabrication of a simplified Vertical Metal Oxide Semiconductor Field Effect Transistor (VMOSFET). Numbers of the form 8xx appearing FIGS. 8A to 8C correspond to numbers in the form 4xx in FIGS. 4A to 4H, and respectively correspond to the substantially identical structures.

Before the deposition of the dielectric layer 418 shown in FIG. 8A, a doped source region 826 was formed in the doped regions 406. In embodiments where the doped regions 406 is p-type material, the doped source region 826 may be n-type material.

At FIG. 8A, an opening 832 has been formed in the dielectric layer 418 over an active area of the epitaxy 404 and over portions of the doped regions 406 and portions of the doped source region 826. Here, the doped regions 406 correspond to p-bodies of a VMOSFET, though some details of the doped regions 406 well-known in the art are not shown in the interest of clarity.

At FIG. 8B, a shallow trench has been formed in the middle of the active area inside the opening 832, and a dielectric layer 834 has been formed in the shallow trench.

At FIG. 8C, an additional dielectric layer has been formed to create a dielectric layer 836, which may include the dielectric layer 418. A portion of the dielectric layer 836 comprises a gate dielectric, and a gate electrode 838 has been formed (in an embodiment, from doped polysilicon) over the gate dielectric portion of the dielectric layer 836.

FIG. 9 illustrates an additional step performed after the steps shown in FIGS. 4A through 4H and FIGS. 8A through 8C in a semiconductor device manufacturing process according to another embodiment.

At FIG. 9, openings have been formed in the dielectric layer 836 to expose portions of the doped regions 406 and the doped source regions 826. Thin conductive layers 940 have been formed over the surfaces of the doped regions 406 and the doped source regions 826 exposed in the openings in the dielectric layer 836, and in an embodiment comprise nickel silicide. A source electrode 942 has been formed to provide electrical connection to the doped regions 406 and doped source regions 826 through the thin conductive layers 940 and are formed to extend over at least a portion of the carbon fill 416.

Accordingly, FIG. 9 shows an intermediate stage of a process of manufacturing a VMOSFET having high-voltage terminations formed using a floating carbon fill in a deep trench.

FIG. 10 illustrates an additional step performed after the steps shown in FIGS. 4A through 4H and FIGS. 8A through 8C in a semiconductor device manufacturing process according to another embodiment.

At FIG. 10, openings have been formed in the dielectric layer 836 to expose portions of the doped regions 406, portions of the doped source regions 826, and portions of the carbon fill 416. Thin conductive layers 940 have been formed over the surfaces of the doped regions 406 and the doped source regions 826 exposed in the openings in the dielectric layer 836, and in an embodiment comprise nickel silicide. A source electrode 942 has been formed to provide electrical connection to the doped regions 406 and doped source regions 826 through the thin conductive layers 940, and to the carbon fill 416.

Accordingly, FIG. 10 shows an intermediate stage of a process of manufacturing a VMOSFET having high-voltage terminations formed using a grounded carbon fill in a deep trench.

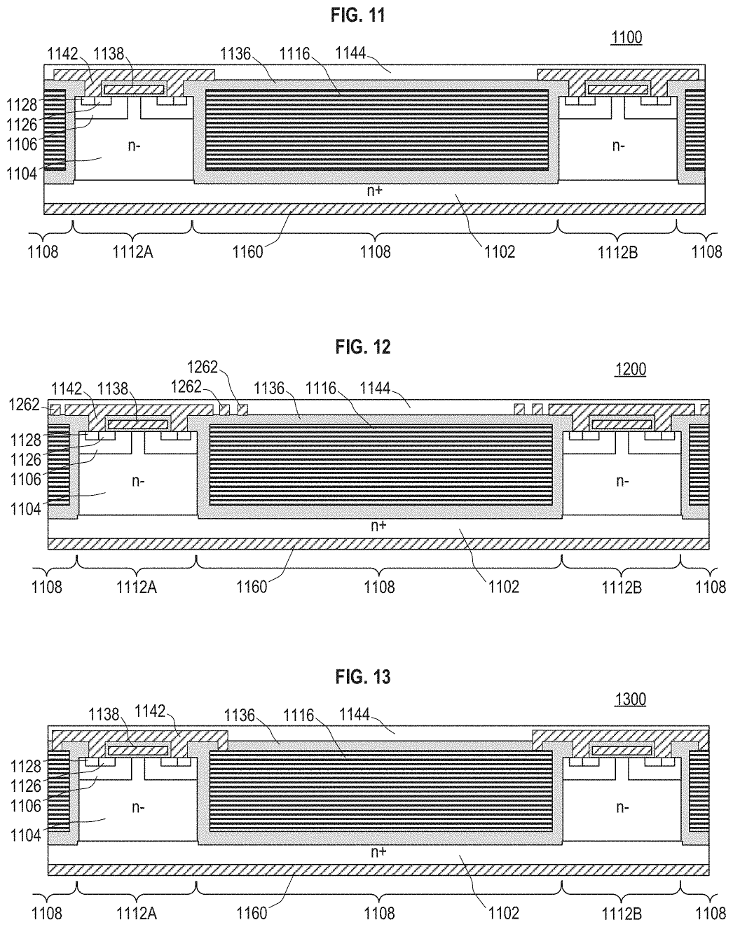

FIG. 11 illustrates a cross-section of a semiconductor device 1100 according to an embodiment. In FIG. 11, numbers of the form 11xx correspond to numbers of the form 1xx in FIG. 1, and respectively indicate substantially similar structures.

The device 1100 comprises a substrate 1102 on which an epitaxy 1104 has been formed.

Doped regions 1106 are formed in active areas 1112A and 1112B (collectively, active regions 112) of the epitaxy 1104 between deep trenches 1108. The doped regions 1106 correspond to body regions of an n-channel VMOSFETs, may be p-type regions, and accordingly may include a heavily doped n-type source regions 1126 formed towards a center of the respective active region 1112 and a heavily doped p-type region 1128 formed towards a peripheral region of that active region 1112 and adjacent to an n-doped source region 1126.

Each of the trenches 1108 is lined with a dielectric 1136 that is also formed over the top of the epitaxy 1104 and the doped region 1106 and that may form a gate dielectric under a gate electrode 1138. In embodiments, the dielectric 1136 includes silicon dioxide.

A carbon fill 1116 is formed inside the dielectric 1136 lining each trench 1108. In embodiments, the carbon fill 1116 is formed by pyrolysis of an organic material, such as a photoresist. The carbon fill 1116 in the embodiment of FIG. 11 is “floating,” in that it is not electrically connected to any of the active portions of the device 1100. However, embodiments are not limited to floating carbon fill.

First electrodes 1142 are formed over and in electrical contact with the doped regions 1126 and 1128, and extend over at least parts of carbon fill 1116 in the trenches 1108. The first electrodes 1142 provides electrical connections to source and body regions of the VMOSFETs of device 1100.

The first electrode 1142 may comprise aluminum, among other conductors, and is electrically connected to the doped regions 1126 and 1128. In some embodiments, the first electrode 1142 is electrically connected to the doped regions 1126 and 1128 through a thin conductive layer (not shown).

The portion of the first electrode 1142 extending over the carbon fill 1116 in the trenches 1108 may operate as a field plate to increase the breakdown voltage of the VMOSFET of device 1100.

A second electrode 1160 comprising a conductor, such as silver, is formed over a bottom surface of the substrate 1102 and provides an electrical connection to drains of the VMOSFETs in the active areas 1112.

A passivation layer 1144 is formed over the first electrode 1142 and the dielectric 1136. In embodiments, the passivation layer comprises silicon oxynitride (SiON).

FIG. 12 illustrates a cross-section of a semiconductor device 1200 according to an embodiment. The device 1200 of FIG. 12 differs from the device 1100 of FIG. 11 by further comprising one or more field rings 1262 disposed on the dielectric 1136 around each of the active regions 1112 and over the carbon fill 1116. The field rings 1262 comprise a conductive material, such as the conductive material used in the first electrode 1142, and are each conductively isolated (that is, not electrically conductively coupled to any active or conductive element of device 1200 or to each other). The field rings 1262, the trenches 1108, the floating carbon fill 1116, and, in some embodiments, a portion of the first electrode 1142 comprise a high-voltage termination for the VMOSFETs in the active areas 1112 of the device 1200.

FIG. 13 illustrates a cross-section of a semiconductor device 1300 according to an embodiment. The device 1300 of FIG. 13 differs from the device 1100 of FIG. 11 by having the carbon fill 1116 conductively connected to the first electrode 1142. Accordingly, the carbon fill 1116 in the device 1300 is grounded, and provides both high-voltage termination and a lower junction capacitance to the VMOSFETs in the active areas 1112 of the device 1300.

In the device 1300 shown in FIG. 13, the device in each of active areas 1112A and 1112B are both connected to the same carbon fill 1116, but embodiments are not limited thereto. In an embodiment, FIG. 13 may correspond to each of the VMOSFETs in the active areas 1112A and 1112B being cells of a same multi-cell VMOSFET. For optimal performance, the VMOSFET operation should be uniform, meaning every cell is in the same operation state. Tying the sources together through the trench conductive fill provide excellent equipotential connection and is therefore beneficial for the VMOSFET performance.

In another embodiment, two trenches replace the single trench 1108 shown in the middle of FIG. 1300, each trench including a lining of dielectric and a carbon fill, so that the active areas 1112A and 1112B are not conductively coupled together by the carbon fill.

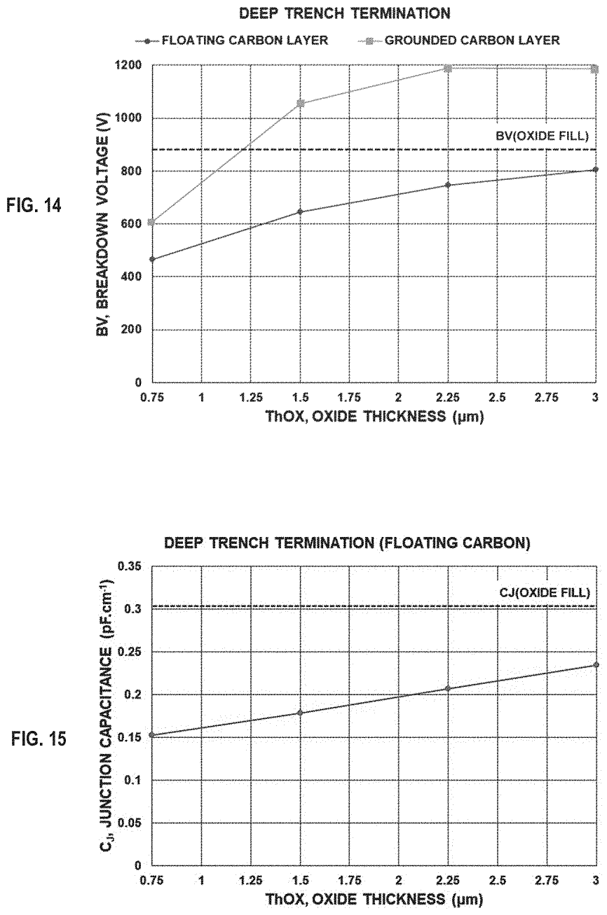

FIG. 14 is a graph of breakdown voltage as function of the thickness of the dielectric layer in the trench between the semiconductor material and the conductive fill for the embodiment of FIG. 1. These results are for a conformal dielectric layer deposition which means the deposited thickness is the same at the bottom and along the side-walls of the trench.

As can be seen in FIG. 14, the breakdown voltage increases with thickness of the dielectric layer. When a grounded carbon fill is used in a deep trench, the breakdown voltage gets higher than the breakdown voltage with a purely dielectric (silicon dioxide) fill for dielectric layer thicknesses above 1.25 μm. On the other hand, when an electrically floating carbon fill is used, the breakdown voltage remains below the breakdown voltage with a purely dielectric (silicon dioxide) fill, even for thick dielectric layers.

FIG. 15 is a graph of junction capacitance as function of the thickness of the dielectric layer in the trench between the semiconductor material and the conductive fill for the embodiment of FIG. 1. These results are for a conformal dielectric layer deposition and for an electrically floating carbon fill.

As can be seen in FIG. 15, a trench lined with a dielectric and filled with an electrically floating carbon layer can be used to provide a high-voltage termination with substantially lower junction capacitance (for example, MOSFET drain-to-source capacitance) compared to using only oxide to fill the trench. In particular, this embodiment is well-suited to reduce the power losses in fast switching and radio-frequency (RF) applications.

Illustrative embodiments have been provided wherein deep trenches are lined with a dielectric, such as silicon dioxide, and then filled with pyrolytically-formed carbon. Such deep trenches may be used to provide high-voltage termination to semiconductor devices, and may improve the breakdown voltages of those devices, decrease a junction capacitance of those devices, or a combination thereof. Because it is easier to produce a deep trench filled according to embodiments than it is to produce a deep trench filled with oxide only, manufacturing of high-frequency and high-voltage semiconductor devices is made easier.

Aspects of the present disclosure have been described in conjunction with the specific embodiments that are presented as illustrative examples, but embodiments are not limited to those shown in the drawings or those mentioned in the accompanying text. Numerous alternatives, modifications, and variations to the disclosed embodiments may be made without departing from the scope of the claims set forth below. Embodiments disclosed herein are not intended to be limiting.

What is claimed is:

1. A semiconductor device comprising:
a deep trench;
a conductive material disposed in the deep trench; and
a dielectric disposed within the deep trench and separating the conductive material from surfaces of the deep trench.

2. The semiconductor device of claim 1, wherein the conductive material is carbon.

3. The semiconductor device of claim 1, wherein the conductive material is conductively isolated.

4. The semiconductor device of claim 3, further comprising:
a first electrode disposed over at least a portion of the conductive material.

5. The semiconductor device of claim 4, wherein the first electrode is conductively isolated.

6. The semiconductor device of claim 4, wherein the first electrode is conductively coupled to an electrode of an active device of the semiconductor device.

7. The semiconductor device of claim 4, wherein the first electrode, the deep trench, and the conductive material comprise a high-voltage termination of an active device of the semiconductor device.

8. The semiconductor device of claim 1, further comprising:
an active device; and
a conductive electrode configured to conductively couple the active device to the conductive material.

9. The semiconductor device of claim 8, wherein the active device comprises a diode, a field effect transistor (FET), an insulated gate bipolar transistor (IGBT) a bipolar junction transistor (BJT), a thyristor, or a combination thereof.

10. The semiconductor device of claim 1, further comprising:
an epitaxial layer;
a doped region disposed in the epitaxial layer; and
a metallurgical junction at a junction of the epitaxial layer and a bottom of the doped region,
wherein the deep trench is disposed in the epitaxial layer, and
wherein the deep trench penetrates the epitaxial layer from a top surface of the epitaxial layer to deeper than a metallurgical junction.

11. A method of manufacturing a semiconductor device, the method comprising:
forming a trench in the semiconductor device;
depositing an organic compound within the trench; and
converting the organic compound to a carbon fill by converting the organic compound to carbon using pyrolysis.

12. The method of claim 11, further comprising:
thinning the organic compound before converting the organic compound to carbon using pyrolysis.

13. The method of claim 11, further comprising forming a layer of dielectric over surfaces of the trench before depositing the organic compound within the trench.

14. The method of claim 11, further comprising:
forming a dielectric layer over the carbon fill.

15. The method of claim 14, further comprising:
forming a conductive electrode over the dielectric layer and over the carbon fill.

16. The method of claim 15, wherein the conductive electrode is conductively coupled to the carbon fill.

17. The method of claim 15, further comprising:
forming an active device in the semiconductor device,
wherein the conductive electrode is conductively coupled to the active device.

18. The method of claim 11, wherein the organic compound is a photoresist.

19. The method of claim 18, wherein the photoresist is deposited using spin coating.

20. The method of claim 11, further comprising:
forming a doped region in the semiconductor device,
wherein the trench is deeper than a deepest portion of the doped region.

21. The method of claim 11, further comprising:
processing the semiconductor device at a temperature of 700 degrees Celsius or more after converting the organic compound to a carbon fill using pyrolysis.
